(19) United States
(12) Patent Application Publication
(10) Pub. No.: US 2019/0252408 A1
(43) Pub. Date: Aug. 15, 2019

(54) STAGGERED SELF ALIGNED GATE CONTACT

(71) Applicant: QUALCOMM Incorporated, San Diego, CA (US)

(72) Inventors: Hyeokjin LIM, San Diego, CA (US); Xiangdong CHEN, San Diego, CA (US); Renukprasad HIREMATH, Hillsboro, OR (US); Rui LI, San Diego, CA (US); Venugopal BOYNAPALLI, San Marcos, CA (US)

(21) Appl. No.: 15/895,094

(22) Filed: Feb. 13, 2018

(51) Int. Cl. H01L 27/118; H01L 21/768; H01L 27/02

(52) U.S. Cl. CPC H01L 27/11807; H01L 21/76897; H01L 27/0207; H01L 2027/11885; H01L 2027/11855; H01L 2027/11866; H01L 2027/11816

(57) ABSTRACT

A semiconductor die includes a first diffusion region and a plurality of gates extending across the diffusion region. The plurality of gates are substantially parallel to each other. An interconnect layer above the diffusion region and plurality of gates includes a plurality of signal traces extending in a direction substantially perpendicular to the gates. At least two of the plurality of signal traces are located directly above the diffusion region such that at intersections of two gates with two separate signal traces are in the active transistor region, that is the portion of the gate extending over the diffusion region. Gate contacts coupling the two gates to the two separate signal traces are staggered by coupling to different signal traces.

### BACKGROUND

### I. Field of the Disclosure

Aspects of the disclosure relates generally to metal routing on a semiconductor die, and more particularly, to reducing spacing between transistor gate contacts in a standard cell.

### II. Background

A semiconductor die typically includes many standard cells, where a standard cell typically includes two or more transistors that are interconnected to form a circuit. Standard cells are usually replicated numerous times on the die. As the feature size of devices in the die continue to reduce the spacing between contacts on the die also reduce. Reduced spacing of contacts can result in potential of short circuits between adjacent contacts. For example, in traditional logic standard cells transistor gate contacts are separated from source/drain contacts to prevent short circuits, but the separation becomes difficult as the transistor dimensions decrease.

### SUMMARY OF THE DISCLOSURE

The described aspects generally relate to one or more cells, or standard cells in a semiconductor die. Aspects include a semiconductor die that includes a first diffusion region. A plurality of gates extending across the diffusion region. The plurality of gates are substantially parallel to each other. There is a interconnect layer above the diffusion region and plurality of gates. The interconnect layer includes a plurality of signal traces extending in a direction substantially perpendicular to the gates. At least two of the plurality of signal traces are located directly above the diffusion region such that at intersection of two gates with two separate signal traces are in the active transistor region, or the portion of the gate extending over the diffusion region. Gate contacts coupling the two gates to the two separate signal traces are staggered by coupling to different signal traces.

The diffusion region can be a P type diffusion region or an N type diffusion region. The standard cell can include a second diffusion region separated from the first diffusion region by an isolation area, wherein the plurality of gates extend over both the first diffusion region and the second diffusion region. Also two adjacent gates can have a portion removed over the isolation region to electrically separate the gates of transistors form in the first and second diffusion regions.

Additional aspects include a standard cell in a semiconductor die including a first diffusion region and a second diffusion region. A plurality of gates extending, in a first direction substantially parallel to each other, across the first and second diffusion regions. A plurality of interconnect traces above the diffusion regions and the plurality of gates, the plurality of interconnect traces extending in a second direction substantially parallel to each other and substantially perpendicular to the direction of the plurality of gates At least two of the interconnect traces are directly above the first diffusion region and there are at least two interconnect traces directly above the second diffusion region.

Another aspect includes a standard cell in a semiconductor die including a P type diffusion region and an N type diffusion region, wherein the P type diffusion region is separated from the N type diffusion by an isolation region. A first gate and a second gate extending substantially parallel to each other and extending over the P type diffusion region and the N type diffusion region, thereby forming a first P MOS transistor, a second P MOS transistor, a first N MOS transistor, and a second N MOS transistor. A plurality of interconnect traces in a first metal layer extending substantially parallel to each other in a direction substantially perpendicular to the first and second gates. A plurality of interconnect traces in a second metal layer extending substantially parallel to each other in a direction substantially perpendicular to the plurality of interconnect traces in the first metal layer. A cut region of the first and second gate separating the gate of the first P MOS transistor from the gate of the first N MOS transistor, and separating the gate of the second P MOS transistor from the gate of the second N MOS transistor. A first gate contact coupling the gate of the first P MOS transistor to a first interconnection trace in the first metal layer directly above the P type diffusion region. The first interconnect trace in the first layer is coupled to a first interconnect trace in the second interconnect layer. The first interconnect trace in the second interconnect layer coupled to a second interconnect trace in the first interconnect layer directly above the N diffusion region. The second interconnect trace in the first interconnect layer is coupled to a second gate contact coupled to the gate of the second N MOS transistor. And a third gate contact coupling the gate of the first N MOS transistor to a third interconnection trace in the first metal layer directly above the N type diffusion region, The third interconnect trace in the first layer is coupled to a second interconnect trace in the second interconnect layer. The second interconnect trace in the second interconnect layer is coupled to a fourth interconnect trace in the first interconnect layer directly above the P diffusion region. The fourth interconnect trace in the first interconnect layer coupled to a fourth gate contact coupled to the gate of the second P MOS transistor.

The standard cell can include a third gate extending substantially parallel to the first and second gates and extending over the P type diffusion region and the N type diffusion region, forming a third P MOS transistor and third N MOS transistor, thereby forming a latch circuit. The first gate contact and fourth gate contact are stagger by being on different interconnect traces in the first interconnect layer. And the second gate contact and third gate contact are stagger by being on different interconnect traces in the first interconnect layer.

Additional aspects include a method of forming a semiconductor die. The method includes forming a plurality of gates on a substrate, the gates extending substantially parallel to each other. Diffusing a dopant into the substrate around the gates to form a first diffusion region. Forming an isolation layer over the diffusion region and gates. Forming a interconnect layer above the isolation layer, the interconnect layer includes a plurality of signal traces extending in a direction substantially perpendicular to the gates. At least two of the plurality of signal traces located directly above the diffusion region. The method can also include forming a second diffusion region separated from the first diffusion region by an isolation area, wherein the plurality of gates extend over both the first diffusion region and the second diffusion region, and there are at least two of the plurality of signal traces located directly above the second diffusion region.

### BRIEF DESCRIPTION OF THE FIGURES

The accompanying drawings are presented to aid in the description and illustrations of embodiments and are not intended to be limitations thereof.

FIG. 1 is a diagram of a physical layout of transistors.

FIG. 2 is a diagram illustrating staggered self-aligned gate contact.

FIG. 3 is a diagram illustrating aspects of a staggered self-aligned gate contact.

FIG. 4 is a diagram of a latch circuit 402.

FIG. 5 is a diagram of the cross coupled portion of the latch circuit.

FIG. 6 is a diagram of a typical physical layout of the gate interconnects of the cross coupled portion of the latch circuit.

FIG. 7 is a diagram illustration physical cross coupling of transistor gates in the latch circuit using stagger self-aligned gate contacts.

FIG. 8 is a flow diagram of forming a stagger self-aligned gate contact structure.

The drawings may not depict all components of a particular apparatus, structure, or method. Further, like reference numerals denote like features throughout the specification and figures.

### DETAILED DESCRIPTION

Aspects disclosed in the following description and related drawings are directed to specific embodiments. Alternative embodiments may be devised without departing from the scope of the invention. Additionally, well-known elements may not be described in detail, or may be omitted, so as not to obscure relevant details. Embodiments disclosed may be suitably included in any electronic device.

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. Furthermore, the terminology used herein is for the purpose of describing particular embodiments and is not intended to be limiting

A semiconductor die includes transistors formed on a substrate of the die. The transistors can be formed using a planar process or a non-planar process. The transistors may include planar field effect transistors, FinFET transistors, or other types of transistors.

On the die, two or more transistors may be grouped together to form a cell, in which the transistors in the cell are interconnected to form a circuit. If the circuit implemented in the cell is used multiple times the cell can be replicated as needed. A cell that is implemented with a specified dimension, for example, a fixed height, is often referred to as a standard cell. Multiple standard cells, implementing different circuit functions, can form a standard cell library used to implement complex electronic designs. Using standard cells, such as ones with a fixed height, allows the standard cells to be placed in rows, easing interconnections between the standard cells.

The die also includes multiple interconnect metal layers, in which adjacent interconnect metal layers are separated by one or more insulating layers. In general, for manufacturing purposes metal interconnections on alternating metal layers run in horizontal and vertical straight lines on alternate layers. In some lower metal layers horizontal and vertical straight lines can run in the same metal layer. The die also includes contacts used to electrically couple the transistors to the interconnect metal layers. Connects from one interconnect metal layer to another interconnect layer can be done using conducting vias extending through the intervening insulating layers. The contacts, interconnect metal layers, and vias are used by a designer to interconnect the transistors to form the circuit in the cell.

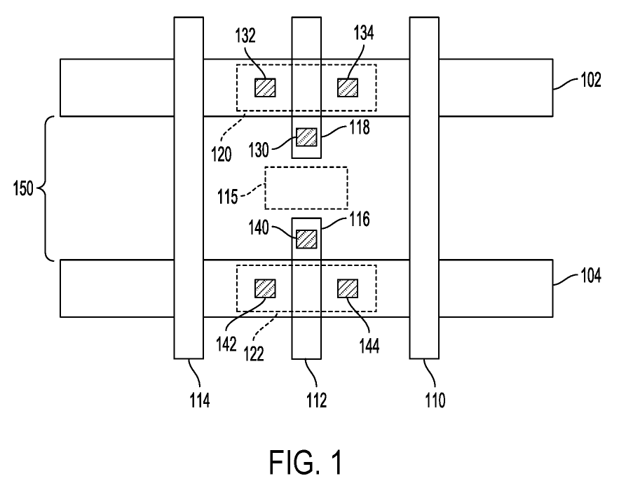

FIG. 1 is a diagram of a physical layout of transistors. The transistors of FIG. 1 can be part of a standard cell. In FIG. 1 there is a P diffusion region 102 and a N diffusion region 104. A first gate 110, a second gate 112, and a third gate 114 extend across the P diffusion region 102 and the N diffusion region 104. The second gate 112 extending over the P diffusion region forms a P type transistor 120 and the second gate 112 extending over the N diffusion region forms an N type transistor 122. A portion 115 of the second gate 112 is removed, or cut, to separate the P type transistor 120 gate from the N type transistor 122 gate.

A P type transistor gate contact 130 is formed on the gate of the P type transistor 120 and a P type transistor source contact 132 and drain contact 134 are formed on the source and drain regions of the P type transistor 120. Similarly, a N type transistor gate contact 140 is formed on the gate of the N type transistor 122 and a N type transistor source contact 142 and drain contact 144 are formed on the source and drain regions of the N type transistor 122.

Between the P diffusion region 102 and N diffusion region 104 is a shallow trench isolation (STI) region 150 that isolates the P type transistor 120 and the N type transistor 122. As can be seen from FIG. 1, the P type transistor gate contact 130 is located on a portion of the P type transistor gate that extends over the STI region 150. Likewise, the N type transistor gate contact 140 is location on a portion of the N type transistor gate that extends over the STI region 150. Locating the P type transistor gate contact 130 over the STI region 150 provides separation between the P type transistor gate contact 130 and the P type transistor source contact 132 and drain contact 134, the separation isolating the contacts from each other to prevent potential short circuits. Locating the N type transistor gate contact 140 over the STI region 150 provides separation between the N type transistor gate contact 140 and the N type transistor source contact 142 and drain contact 144, the separation isolating the contacts from each other to prevent potential short circuits.

As semiconductor die scale smaller the size of standard cells has decreased. As the height of the standard cell has decreased the height of the STI region 150 between the P diffusion region 102 and N diffusion region 104 has decreased. The reduction in the height of the STI region 150 lead to a technique referred to as self-aligned gate contact (SAGC).

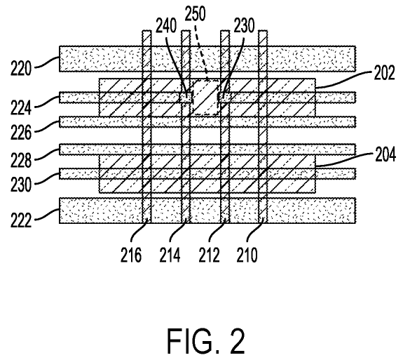

FIG. 2 is a diagram illustrating staggered self-aligned gate contact. In FIG. 2 there is a P diffusion region 202 and an N diffusion region 204. A first gate 210, second gate 212, third gate 214, and fourth gate 216 extend across the P diffusion region 202 and N diffusion region 204. FIG. 2 also shows metal 0 (M0) layer traces. The M0 layer traces include a first Mo trace 220 and a second M0 trace 222 used for power and ground. Metal 0 layer also includes a first M0 signal trace 224, as second M0 signal trace 226, a third M0 signal trace 228, and a fourth M0 signal trace 230.

As shown in FIG. 2, the first M0 signal trance 224 is aligned over the P diffusion region 202 and the fourth M0 signal trace 230 is aligned over the N diffusion region 204. The second M0 signal trace 226 and the third M0 signal trace 228 are aligned between the P diffusion region 202 and the N diffusion region 204. A first gate contact 230 is formed on the second gate 212 over the P diffusion region 202 and a second gate contact 240 is formed on the third gate over the P diffusion region 202. The first gate contact 230 and second gate contact 240 can be coupled to the first M0 signal trace 224. So that the second gate 212 is not electrically coupled to the third gate 214 a portion of the first M0 signal trace is removed, or cut, 250.

Positioning gate contacts over the active transistor region, the portion of the gate extending over the diffusion region, allows for reduced standard cell height by being able to reduce the height of the STI region. However, it is difficult to maintains sufficient spacing between the portions of the first M0 signal trace separated by the cut 250 region.

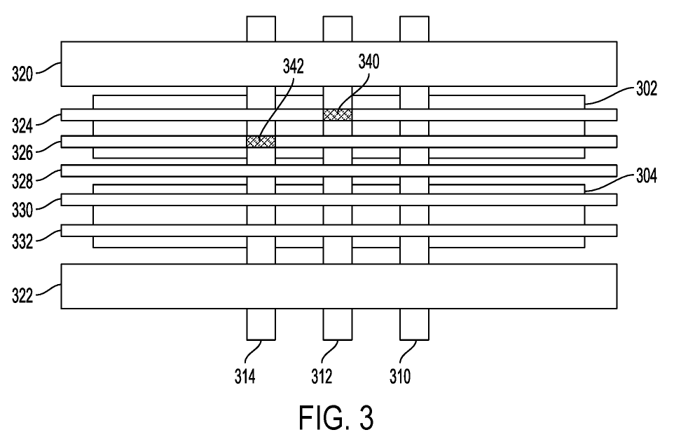

FIG. 3 is a diagram illustrating aspects of a staggered self-aligned gate contact. In FIG. 3 there is a P diffusion region 302 and an N diffusion region 304. A first gate 310, second gate 312, third gate 314, and fourth gate 316 extend across the P diffusion region 302 and N diffusion region 304 in a first direction. FIG. 3 also shows metal 0 (M0) layer traces that run substantial perpendicular to the directions of the gates. The M0 layer traces include a first trace 320 and a second trace 322 used for power and ground. Metal 0 layer also includes a first M0 signal trace 324, as second M0 signal trace 326, a third M0 signal trace 328, a fourth M0 signal trace 330, and a fifth M0 signal trance 332.

As semiconductor die scale, Metal 0 trace width have also scaled allowing the first M0 signal trace 324 and the second M0 signal trace 326 to align over the P diffusion region 302 and the fourth M0 signal trace 330 and the fifth M0 signal trace 332 are aligned over the N diffusion region 304. The third M0 signal trace 328 is aligned between the P diffusion region 302 and the N diffusion region 304. A first gate contact 340 is formed on the second gate 312 and a second gate contact 342 is formed on the third gate 314. By forming the gate contacts on different M0 signal traces in the active transistor region the gate contacts are staggered from each other. In other words, at least two of the plurality of signal traces are located directly above the diffusion region such that at intersections of two gates with two separate signal traces are in the active transistor region, that is the portion of the gate extending over the diffusion region. Gate contacts coupling the two gates to the two separate signal traces are staggered by coupling to different signal traces.

Because the first gate contact 340 is coupled to the first M0 signal trace 324 and the second gate contact 342 is coupled to the second M0 signal trace there is no cut of a M0 signal trace needed to separate the second gate 312 from the third gate 314 while still maintaining sufficient spacing between the first and second gate contacts 340 and 341.

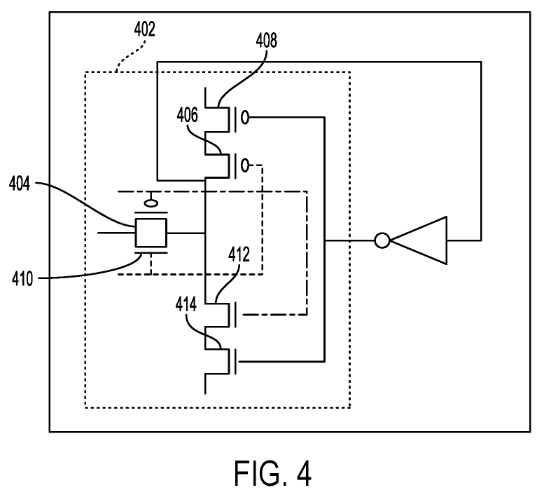

The staggered self-aligned gate contact aspect can be used in many circuit designs and/or standard cells in a die. FIG. 4 is a diagram of a latch circuit 402. Latch circuits are used extensively in semiconductor die. As shown in FIG. 4, the latch circuit 402 comprises a first PMOS transistor 404, a second P MOS transistor 406, and a third P MOS transistor 408. The latch circuit 402 also includes a first NMOS transistor 410, a second N MOS transistor 402, and a third N MOS transistor 412. As shown in FIG. 4 the transistors are cross connected, explained further below, making the physical layout in the die difficult.

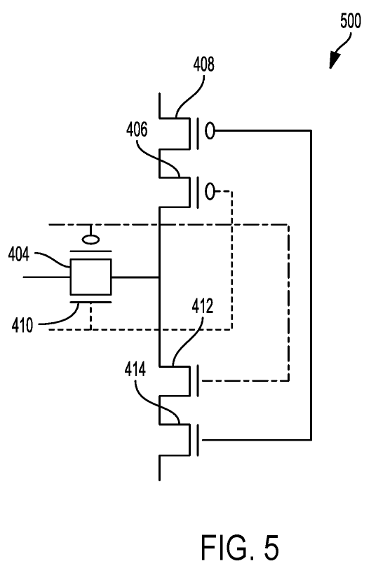

FIG. 5 is a diagram of the cross coupled portion 500 of the latch circuit 402. As shown in FIG. 5 the gate of the first P MOS transistor 404 is coupled to the gate of the second N MOS transistor 412. Likewise, the gate of the first N MOS transistor 410 is coupled to the gate of the second P MOS transistor 406. The gate of third P MOS transistor 408 is coupled to the gate of the third N MOS transistor 414. The source and drain of the first P MOS transistor 404 and the first N MOS transistor 410 are coupled together. The drains of the first P MOS transistor 404 and the first N MOS transistor 410 are also coupled to the drain of the second P MOS transistor 406 and the source of the second N MOS transistor 412. The source of the second P MOS transistor 406 is coupled to the drain of the third P MOS transistor 408. The drain of the second N MOS transistor 412 is coupled to the source of the third N MOS transistor 414.

Typically, the gate connects are made using the lower level metal interconnect layers, closet to the substrate, usually labeled M0, as the lowest level, and M1, the next level. The source and drain connections of the transistors are typically made using higher level metal layers.

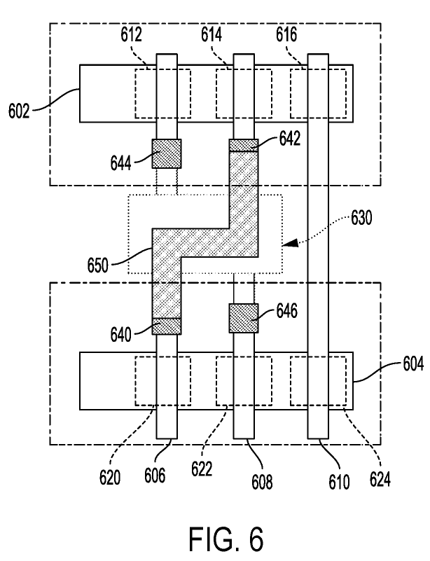

FIG. 6 is a diagram of a typical physical layout 600 of the gate interconnects of the cross coupled portion 500 of the latch circuit 402. In FIG. 6 there is a P diffusion region 602 and an N diffusion region 604. There is a first gate 606, a second gate 608, and a third gate 610 extending across the P diffusion region 602 and the N diffusion region 604. The P diffusion region 602 and the first gate 606 forms a first PMOS transistor 612. The P diffusion region 602 and the second gate 608 forms a second PMOS transistor 614, and he P diffusion region 602 and the third gate 610 forms a third PMOS transistor 616. Likewise, the N diffusion region 604 and the first gate 606, second gate 608, and third gate 360 form a first N MOS transistor 620, a second N MOS transistor 622, and a third N MOS transistor 624 respectively.

To cross couple the gate of the first N MOS transistor 620 to the gate of only the second P MOS transistor 614, and to cross couple the gate of the first P MOS transistor 612 to the gate of only the second N MOS transistor portions of the first gate 606 and the second gate 608 are removed, or cut, 630. Cutting the first gate 606 separates the gates of the first P MOS transistor 612 and the first N MOS transistor 620. Cutting the second gate 608 separates the gates of the first P MOS transistor 612 and the first N MOS transistor 620.

A first gate contact 640 is formed on the gate of the first N MOS transistor 620 and a second gate contact 642 is formed on the gate of the second P MOS transistor 614. A third gate contact 644 is formed on the gate of the first P PMOS transistor 612 and a fourth gate contact 646 is formed on the second N MOS transistor 622. To cross couple the gate of the first N MOS transistor 620 to the gate of the second P MOS transistor 614 metal layer M0 interconnections 650 forms a zigzag connection between the gates. In a similar manner, not shown, to cross couple the gate of the first P MOS transistor 612 to the gate of the second N MOS transistor 622 on another metal interconnections layer forming a similar zigzag connection between the two gates.

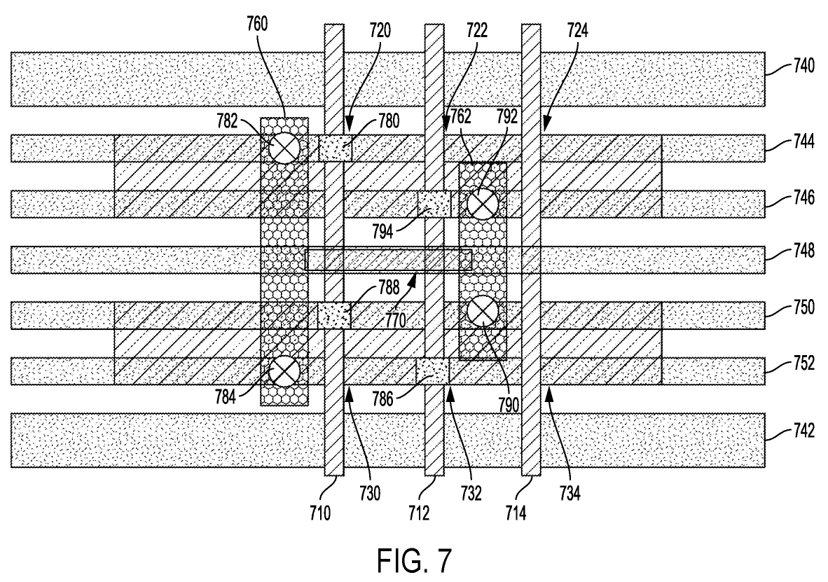

FIG. 7 is a diagram illustration physical cross coupling of transistor gates in the latch circuit using stagger self-aligned gate contacts. As shown in FIG. 7 there is a P diffusion region 702 and an N diffusion region 704. A first gate 710, a second gate 712, and a third gate 714 extend across the P diffusion region 702 and N diffusion region 704. The gates and P diffusion region forms a first P MOS transistor 720, a second P MOS transistor 722 and a third P MOS transistor 724. The gates and the N diffusion region forms a first N MOS transistor 730, a second N MOS transistor 732, and a third N MOS transistor 734.

Metal 0 interconnection layer includes traces that run substantial perpendicular to the gates. There is a first M0 trace 740 and a second M0 trace 742 used to supply power and ground. Metal 0 interconnect layer also includes a first M0 signal trace 744, a second M0 signal trace 746, a third M0 signal trace 748, a fourth M0 signal trace 750 and a fifth M0 signal trace 752. The first M0 signal trace 744 and second M0 signal trace 746 extend above the P diffusion region 702. The fourth M0 signal trace 750 and the fifth M0 signal trace 752 extend above the N diffusion region 804.

Metal 1 interconnect layer includes traces that run substantial perpendicular to the M0 traces and are separated from the M0 interconnect layer by an insulation layer. Metal 1 interconnect layer includes a first M1 signal trace 760 and a second M1 signal trace 862. The gates of the first P MOS transistor 720 and first N MOS transistor 730, and the gates of the second P MOS transistor 722 and second N MOS transistor 732, are separated by removing, or cutting, 870 a portion of the first gate 710 and second gate 712 respectively.

To form the desired cross coupling, the gate of the first P MOS transistor 720 is coupled to the gate of the second N MOS transistor 732 in the following manner. A first gate contact 780 formed on the gate of the first P MOS transistor 720 is coupled to the first M0 signal trance 744. The first M0 signal trace is coupled to the first M1 signal trace 760 by a first via 782. The first M1 signal trace 760 is also coupled to the fifth M0 signal trace 752 by a second via 784. The fifth M0 signal trace 752 is coupled to a second gate contact 786 formed on the gate of the second N MOS transistor 732.

The gate of the first N MOS transistor 730 is coupled to the gate of the second P MOS transistor 722 in the following manner. A third gate contact 788 is formed on the gate of the first N MOS transistor 730 is coupled to the fourth M0 signal trace 750. The fourth M0 signal trace is coupled to the second M1 signal trace 762 by a third via 790. The second M1 signal trace 746 is also coupled to the second M0 signal trace 746 by a fourth via 792. The second M0 signal trace 746 is coupled to a fourth gate contact 794 formed on the gate of the second P MOS transistor 722.

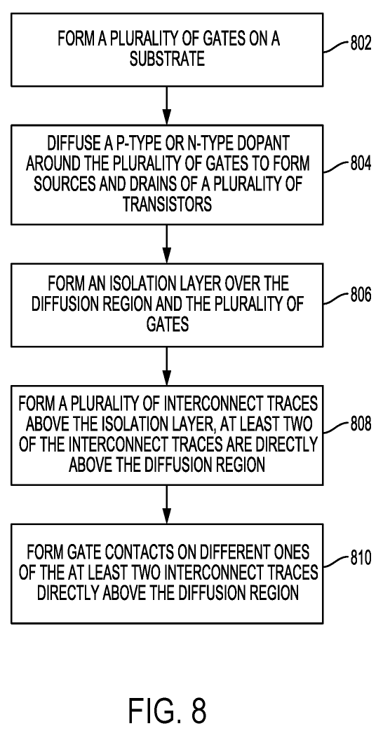

The gates of the third P MOS transistor 874 and third N MOS transistor 734 are coupled because the gate 814 is not cut. As seen from FIG. 8 the cross coupling of the transistors using stagger self-aligned gate contacts is accomplished without having to cut the metal layers. Also, the cross coupling was accomplished without having to form a zig-zag pattern in a metal interconnect layer. These benefits, and others, are the result of the staggered self-aligned gate contact that is supported by reduced widths of the M0 signal traces so that at least two M0 signal traces can be formed over a diffusion region.

FIG. 8 is a flow diagram of forming a stagger self-aligned gate contact structure. Flow begins in block 802 where a plurality of gates are formed on a semiconductor substrate. Flow continues to block 804 where a P-type or an N type dopant is diffused into the substrate around the plurality of gates to form source and drains of transistors. Flow continues to block 806 where an isolation layer is formed over the diffusion region and plurality of gates. Flow continues to block 808 where a plurality of interconnect traces are formed above the isolation layer. At least two of the interconnect traces are directly above the diffusion region. Flow continues to block 810 where gate contacts are formed on different ones of the at least two interconnect traces above the diffusion region.

A semiconductor die incorporating aspects of the stagger self-aligned gate contact arrangement described may be implemented in many different types of devices. For example, a hand-held personal communication system (PCS) unit, a portable data unit such as a personal digital assistant (PDA), a GPS enabled device, a navigation device, a set top box, a laptop, a tablet, a desktop computer, a data center server, a music player, a video player, an entertainment unit, a fixed location data unit such as a meter reading equipment, or a communications device, including an RF front end module, or combinations thereof. The disclosure is not limited to these exemplary illustrated units.

The various illustrative logical blocks, modules, and circuits described in connection with the aspects disclosed herein may be implemented or performed in an integrated circuit (IC), a system on a chip (SoC), an Application Specific Integrated Circuit (ASIC), a Field Programmable Gate Array (FPGA) or other programmable logic device, discrete gate or transistor logic, discrete hardware components, or any combination thereof designed to perform the functions described herein.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A semiconductor die comprising:
a first diffusion region;
a plurality of gates extending, substantially parallel to each other, across the diffusion region;
a interconnect layer above the diffusion region and plurality of gates, the interconnect layer comprises a plurality of signal traces extending in a direction substantially perpendicular to the gates;
at least two of the plurality of signal traces located directly above the diffusion region.

2. The standard cell of claim 1, further comprising a plurality of gate contacts.

3. The standard cell of claim 2, a first gate contact is coupled to a first signal trace located directly above the diffusion region, and a second gate contact is coupled to a second signal trace located directly above the diffusion region.

4. The standard cell of claim 1, wherein the diffusion region is a P type diffusion region.

5. The standard cell of claim 1, wherein the diffusion region is an N type diffusion region.

6. The standard cell of claim 1, further comprising a second diffusion region separated from the first diffusion region by a isolation area, where in the plurality of gates extend over both the first diffusion region and the second diffusion region.

7. The standard cell of claim 6, wherein two adjacent gates have a portion removed over the isolation region.

8. The standard cell of claim 6, wherein the first diffusion region is a P type diffusion region and the second diffusion region in an N type diffusion region.

9. A standard cell in a semiconductor die comprising:
a first diffusion region;
a second diffusion region;
a plurality of gates extending, in a first direction substantially parallel to each other, across the first and second diffusion regions;
a plurality of interconnect traces above the diffusion regions and the plurality of gates, the plurality of interconnect traces extending in a second direction substantially parallel to each other and substantially perpendicular to the direction of the plurality of gates;
wherein there are at least two interconnect traces directly above the first diffusion region and there are at least two interconnect traces directly above the second diffusion region.

10. The standard cell of claim 9, wherein the plurality of gates comprise a first gate, a second gate, and a third gate.

11. The standard cell of claim 9, further comprising a first gate contact coupling a first gate to a first interconnect directly above the first diffusion region and a second gate contact coupling a second gate to a second interconnect directly above the first diffusion region.

12. A standard cell in a semiconductor die comprising:
a P type diffusion region and an N type diffusion region, wherein the P type diffusion region is separated from the N type diffusion by an isolation region;
a first gate and a second gate extending substantially parallel to each other and extending over the P type diffusion region and the N type diffusion region, thereby forming a first P MOS transistor, a second P MOS transistor, a first N MOS transistor, and a second N MOS transistor;
a plurality of interconnect traces in a first metal layer extending substantially parallel to each other in a direction substantially perpendicular to the first, second, and third gates;
a plurality of interconnect traces in a second metal layer extending substantially parallel to each other in a direction substantially perpendicular to the plurality of interconnect traces in the first metal layer;
a cut region of the first and second gate separating the gate of the first P MOS transistor from the gate of the first N MOS transistor, and separating the gate of the second P MOS transistor from the gate of the second N MOS transistor;
a first gate contact coupling the gate of the first P MOS transistor to a first interconnection trace in the first metal layer directly above the P type diffusion region, the first interconnect trace in the first layer coupled to a first interconnect trace in the second interconnect layer, the first interconnect trace in the second interconnect layer coupled to a second interconnect trace in the first interconnect layer directly above the N diffusion region, the second interconnect trace in the first interconnect layer coupled to a second gate contact coupled to the gate of the second N MOS transistor; and
a third gate contact coupling the gate of the first N MOS transistor to a third interconnection trace in the first metal layer directly above the N type diffusion region, the third interconnect trace in the first layer coupled to a second interconnect trace in the second interconnect layer, the second interconnect trace in the second interconnect layer coupled to a fourth interconnect trace in the first interconnect layer directly above the P diffusion region, the fourth interconnect trace in the first interconnect layer coupled to a fourth gate contact coupled to the gate of the second P MOS transistor.

13. The standard cell of claim 12 further comprising:
a third gate extending substantially parallel to the first and second gates and extending over the P type diffusion region and the N type diffusion region, thereby forming a third P MOS transistor and third N MOS transistor, thereby forming a latch circuit.

14. The standard cell of claim 12, wherein the first gate contact and fourth gate contact are stagger by being on different interconnect traces in the first interconnect layer.

15. The standard cell of claim 12, wherein the second gate contact and third gate contact are stagger by being on different interconnect traces in the first interconnect layer.

16. The standard cell of claim 12, wherein the first trace in the second interconnect layer is coupled to the first and second interconnect traces in the first interconnect layer by vias.

17. The standard cell of claim 12, wherein the second trace in the second interconnect layer is coupled to the third and fourth interconnect traces in the first interconnect layer by vias.

18. A method of forming a semiconductor die comprising:
forming a plurality of gates on a substrate, the gates extending substantially parallel to each other;
diffusing a dopant into the substrate around the gates to form a first diffusion region;
forming an isolation layer over the diffusion region and gates;
forming a interconnect layer above the isolation layer, the interconnect layer comprises a plurality of signal traces extending in a direction substantially perpendicular to the gates;
at least two of the plurality of signal traces located directly above the diffusion region.

19. The method of claim 18 wherein a first gate contact is coupled to a first signal trace located directly above the diffusion region, and a second gate contact is coupled to a second signal trace located directly above the diffusion region.

20. The method of claim 18, further comprising a second diffusion region separated from the first diffusion region by an isolation area, wherein the plurality of gates extend over both the first diffusion region and the second diffusion region, and there are at least two of the plurality of signal traces located directly above the second diffusion region.
